(19) United States
(12) Patent Application Publication
(10) Pub. No.: US 2016/0079373 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Takeshi UCHIHARA, Kawaguchi Saitama (JP); Wataru SAITO, Kawasaki Kangawa (JP); Takaaki YASUMOTO, Kawasaki Kanagawa (JP); Naoko YANASE, Inagi Tokyo (JP)

(21) Appl. No.: 14/635,315

(22) Filed: Mar. 2, 2015

(30) Foreign Application Priority Data
Sep. 12, 2014 (JP) 2014-186385

(51) Int. Cl. H01L 29/40; H01L 29/51; H01L 29/78; H01L 29/417

(52) U.S. Cl. CPC H01L 29/404; H01L 29/41775; H01L 29/51; H01L 29/518; H01L 29/78

(57) ABSTRACT

A semiconductor device includes a compound semiconductor layer, an insulating element, and a conductive element. The conductive element includes a plurality of conductive regions which are spaced from the compound semiconductor layer in a first direction. The insulating element is provided between the compound semiconductor layer and the conductive element. A length of each of the plurality of conductive regions in a second direction which intersects the first direction becomes longer the farther the individual one of the plurality of conductive regions is spaced from the compound semiconductor layer.

### CROSS-REFERENCE TO RELATED APPLICATION

This application is based upon and claims the benefit of priority from Japanese Patent Application No. 2014-186385, filed Sep. 12, 2014, the entire contents of which are incorporated herein by reference.

### FIELD

Embodiments described herein relate generally to a semiconductor device.

### BACKGROUND

A semiconductor device, such as a horizontal type field effect transistor (FET), can reduce the electric field on a lower part of an electrode by employing a field plate structure, and thus enhance breakdown voltage characteristics of the device. In such a semiconductor device, it is desirable to further enhance the breakdown voltage.

### DESCRIPTION OF THE DRAWINGS

FIG. 1A is a schematic cross-sectional view illustrating an example of the semiconductor device according to the first embodiment.

FIG. 1B is a schematic plan view illustrating an example of the semiconductor device according to the first embodiment.

FIG. 2 is a schematic cross-sectional view illustrating another semiconductor device according to the first embodiment.

FIG. 3 is a schematic cross-sectional view illustrating a semiconductor device according to a reference example.

FIG. 4 is a schematic view illustrating an ideal FP structure.

FIG. 5 is a schematic cross-sectional view illustrating a semiconductor device according to a second embodiment.

FIG. 6 is a schematic cross-sectional view illustrating a semiconductor device according to a third embodiment.

FIGS. 7A to 7D are schematic cross-sectional views illustrating a manufacturing process of the semiconductor device according to the embodiment.

### DETAILED DESCRIPTION

The exemplary embodiments are to provide a semiconductor device having a high breakdown voltage.

In general, according to one embodiment, a semiconductor device includes a compound semiconductor layer, an insulating element, and a first conductive element. The first conductive element includes a plurality of conductive regions which are spaced a different distance in a first direction from the compound semiconductor layer. The insulating element is located between the compound semiconductor layer and the first conductive element. A length of the individual conductive regions, along a second direction which intersects the first direction, of each of the plurality of conductive regions is longer in conductive regions which are spaced farther from the compound semiconductor layer than conductive layers spaced from, and closer to the compound semiconductor layer.

Hereinafter, exemplary embodiments will be described with reference to the drawings.

In addition, the drawings are schematic or conceptual, and relationships between a thickness and a width of each part, or a ratio of sizes between the parts, are not necessarily limited to be the same as those in an actual device. In addition, even when the same parts are shown in multiple Figures, the dimensions or the ratio between the parts may be expressed differently.

In addition, in the specification and each drawing, the same configuration elements as those which were described in a previously discussed figure or embodiment will be given the same reference numerals, and the description thereof will be appropriately omitted.

### First Embodiment

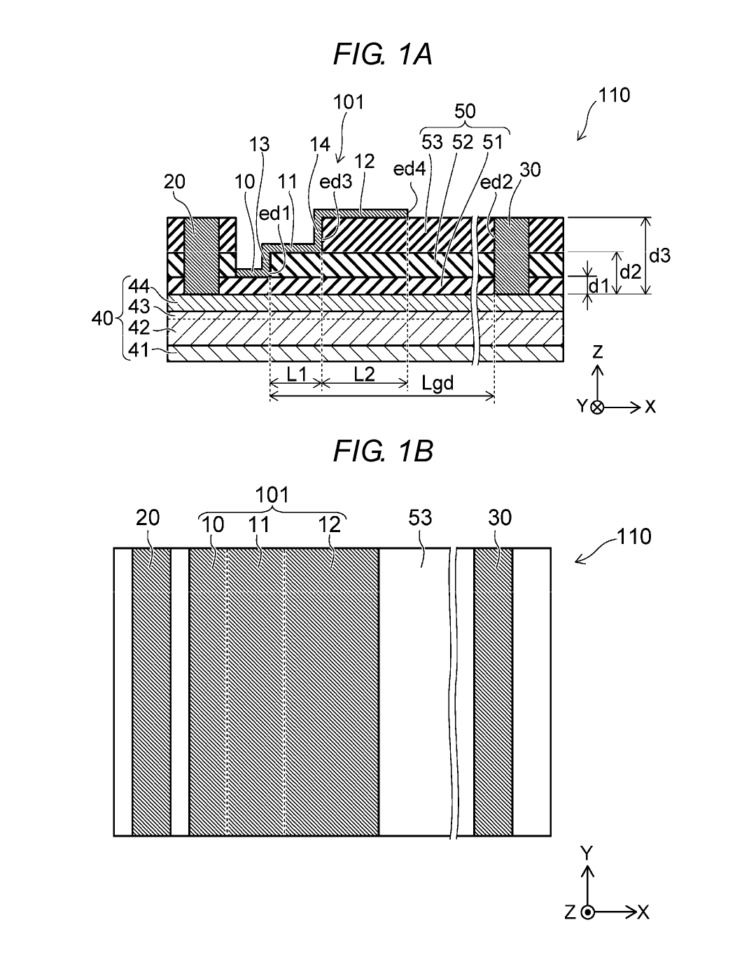

FIG. 1A is a schematic cross-sectional view illustrating an example of the semiconductor device according to the first embodiment.

FIG. 1B is a schematic plan view illustrating an example of the semiconductor device according to the first embodiment.

A semiconductor device 110 of the embodiment includes a compound semiconductor layer 40, a first conductive element 101, and an insulating element 50. The semiconductor device 110 of the embodiment is a horizontal type field effect transistor (FET) which uses a compound semiconductor.

The compound semiconductor is a generic term for a semiconductor which includes two or more types of elements, such as elements from 3-5 group (GaAs, GaN, or InP), elements from 2-6 group (CdTe, ZnSe, or CdS), or elements from 4-4 group (SiC, or SiGe). The compound semiconductor includes a nitride semiconductor, for example.

As a material of the compound semiconductor layer 40, for example, GaN (gallium nitride) is used. As a material of the compound semiconductor layer 40, for example, AlN (aluminum nitride), InN (indium nitride), and a nitride semiconductor which is provided with an intermediate composition of AlN and InN, may be used. As a material of the compound semiconductor layer 40, for example, SiC (silicon carbide) may be used. The compound semiconductor layer 40 is formed by an epitaxial growth method on a substrate (not illustrated), for example.

The compound semiconductor layer 40 includes, for example, a first semiconductor layer 41, a second semiconductor layer 42, and a third semiconductor layer 44. The first semiconductor layer 41 is a GaN layer which is doped by C (carbon) with high concentration. The second semiconductor layer 42 is a channel layer, and for example, a GaN layer. The second semiconductor layer 42 is provided on the first semiconductor layer 41. The third semiconductor layer 44 is a barrier layer, and for example, an AlGaN (aluminum gallium nitride) layer. The third semiconductor layer 44 is provided on the second semiconductor layer 42. In the vicinity of an interface between the second semiconductor layer 42 and the third semiconductor layer 44, a two-dimensional electron gas region (2DEG) 43 is created in which the stress imposed by the mismatch of the two semiconductor layers generates a layer of free electrons and high electron mobility (2DEG) 43 is formed.

In addition, in the example, a stacking direction of the sub-layers of the compound semiconductor layer 40 is a Z-axis direction. One direction which is perpendicular to the Z-axis direction is an X-axis direction. One direction which is perpendicular to the Z-axis direction and the X-axis direction is a Y-axis direction. A first direction is, for example, the Z-axis direction. A second direction is, for example, the X-axis direction. A third direction is, for example, the Y-axis direction.

The insulating element 50 includes a first insulation layer 51, a second insulation layer 52, and a third insulation layer 53. The first insulation layer 51 is provided on the third semiconductor layer 44. The second insulation layer 52 is provided on the first insulation layer 51. The third insulation layer 53 is provided on the second insulation layer 52.

The first conductive element 101 includes a gate electrode 10 (first conductive region), a first field plate electrode (hereinafter, referred to as a first FP electrode) (second conductive region), and a second field plate electrode (hereinafter, referred to as a second FP electrode) (third conductive region). The gate electrode 10 is provided to be apart from the compound semiconductor layer 40 in the Z-axis direction. The gate electrode 10 is provided on the first insulation layer 51. The first FP electrode 11 is electrically connected to the gate electrode 10, and is provided on the second insulation layer 52. The second FP electrode 12 is electrically connected to the first FP electrode 11, and is provided on the third insulation layer 53. Each of the first FP electrode 11 and the second FP electrode 12 is provided to be spaced from the compound semiconductor layer 40 in the Z-axis direction.

The insulating element 50 is located between the compound semiconductor layer 40 and the first conductive element 101. In other words, the insulating element 50 is provided between the compound semiconductor layer 40 and the gate electrode 10, between the compound semiconductor layer 40 and the first FP electrode 11, and between the compound semiconductor layer 40 and the second FP electrode 12.

A first distance along the Z-axis direction between the compound semiconductor layer 40 and the gate electrode 10 is shorter than a second distance along the Z-axis direction between the compound semiconductor layer 40 and the first FP electrode 11. A third distance along the Z-axis direction between the compound semiconductor layer 40 and the second FP electrode 12 is longer than the second distance. A difference between the first distance and the second distance is smaller than a difference between the second distance and the third distance. A first length along the X-axis direction of the first FP electrode 11 is shorter than a second length along the X-axis direction of the second FP electrode 12.

In other words, a first distance d1 along the Z-axis direction between the compound semiconductor layer 40 and the gate electrode 10, a second distance d2 along the Z-axis direction between the compound semiconductor layer 40 and the first FP electrode 11, and a third distance d3 along the Z-axis direction between the compound semiconductor layer 40 and the second FP electrode 12 satisfy a relationship of d1<(d2−d1)<(d3−d2).

A first length L1 along the X-axis direction of the first FP electrode 11 and a second length L2 along the X-axis direction of the second FP electrode 12 satisfy a relationship of L1<L2.

In other words, the distance between the first conductive element 101 and the insulating element 50 changes in a step shape between the first distance d1 and the second distance d2, and changes in a step shape between the second distance d2 and the third distance d3.

Here, the distance does not mean a distance between the centers of two objects, but means a distance (interval) along the Z-axis direction between the surface of the lower side of one unit (layer) and the surface of the upper side of the next unit object (layer). For example, the first distance d1 is a distance (interval) along the Z-axis direction between the upper surface of the compound semiconductor layer 40 and the lower surface of the gate electrode 10. The second distance d2 and the third distance d3 also have a similar meaning.

In this manner, for example, a step unit in a step shape is provided in an insulating element, and a conductive region (electrode) is provided along the exposed end region of the step unit. As it is farther separated from the compound semiconductor layer, a thickness of the insulating element gradually becomes thicker and a length of the electrode gradually becomes longer. Accordingly, it is possible to reduce an electric field which is generated in the lower part of the electrode.

The semiconductor device 110 further includes a source electrode 20 (second conductive element) and a drain electrode 30 (third conductive element). The source electrode 20 is electrically connected to the compound semiconductor layer 40. For example, the source electrode 20 is in contact with the compound semiconductor layer 40. The drain electrode 30 is spaced from the source electrode 20 in the X-axis direction, and is electrically connected to the compound semiconductor layer 40. For example, the drain electrode 30 is in contact with the compound semiconductor layer 40. The first conductive element 101 is disposed between the source electrode and the drain electrode 30. In addition, in the specification, “an electric connection” includes not only a case of a direct contact, but also a case where other conductive materials or the like are interposed therebetween.

As materials of the gate electrode 10, the source electrode 20, and the drain electrode 30, for example, at least any of metals, such as aluminum (Al), nickel (Ni), copper (Cu), or titanium (Ti), are used.

In the semiconductor device 110, a current flows between the source 20 and the drain 30 via the high electron mobility region 43 which is created at the interface between the second semiconductor layer 42 and the third semiconductor layer 44. As a gate bias is applied to the gate electrode 10, the current between the source and the drain is controlled.

The first FP electrode 11 and the second FP electrode 12 control an electric field between a gate and the drain, and suppress a change in characteristics of the semiconductor device 110. For example, electric field concentration which is provoked at an end on the drain electrode 30 side of the gate electrode 10 is reduced. As materials of the first FP electrode 11 and the second FP electrode 12, for example, at least any of metals, such as aluminum (Al), nickel (Ni), copper (Cu), or titanium (Ti), are used.

The gate electrode 10 is provided spaced from the compound semiconductor layer 40 in the Z-axis direction. The source electrode 20 is provided to be in contact with the third semiconductor layer 44, for example. It is desirable that the source electrode 20 come into ohmic contact with the third semiconductor layer 44. For example, the drain electrode 30 is provided to be in contact with the third semiconductor layer 44. It is desirable that the drain electrode 30 come into ohmic contact with the third semiconductor layer 44.

The first FP electrode 11 is spaced from the compound semiconductor layer 40 in the Z-axis direction, and is electrically connected to the gate electrode 10. The first FP electrode 11 has the first length L1 in the X-axis direction. In this example, the gate electrode 10 and the first FP electrode 11 are linked to each other by a first linking unit 13. The second FP electrode 12 is spaced from the compound semiconductor layer 40 in the Z-axis direction, and is electrically connected to the first FP electrode 11. The second FP electrode 12 has the second length L2 in the X-axis direction which is longer than the first length L1. In this example, the first FP electrode 11 and the second FP electrode 12 are linked to each other by a second linking unit 14. The first FP electrode 11, the second FP electrode 12, the first linking unit 13, and the second linking unit 14 may be formed to be integrated with the gate electrode 10.

For example, the gate electrode 10 and the first FP electrode 11 may be formed as floating electrodes. For example, the gate electrode 10 and the first FP electrode 11 may be disposed being separated from each other in the conductive element 101, and may be electrically connected to each other at an end part or the like of the semiconductor device 110. Similarly, the first FP electrode 11 and the second FP electrode 12 may be formed separated from each other. For example, the first FP electrode 11 and the second FP electrode 12 may be disposed separated from each other in the conductive element 101, and may be electrically connected to each other at the end part or the like of the semiconductor device 110.

The first insulation layer 51 is provided between the compound semiconductor layer 40 and the gate electrode 10, between the compound semiconductor layer 40 and the first FP electrode 11, and between the compound semiconductor layer 40 and the second FP electrode 12. The first insulation layer 51 has a first thickness (a thickness which corresponds to the above-described d1, hereinafter, is referred to as a first thickness d1) in the Z-axis direction. In this example, the first insulation layer 51 is provided on the compound semiconductor layer 40, and the gate electrode 10 is provided on the first insulation layer 51. For example, the first insulation layer 51 functions as a gate insulation layer.

The second insulation layer 52 is provided between the first insulation layer 51 and the first FP electrode 11, and between the first insulation layer 51 and the second FP electrode 12. The second insulation layer 52 has a second thickness (a thickness which corresponds to the above-described (d2−d1), hereinafter, is referred to as a second thickness (d2−d1)) along the Z-axis direction which is thicker than the first thickness d1. In this example, the second insulation layer 52 is provided on the first insulation layer 51, and the first FP electrode 11 is provided on the second insulation layer 52.

The third insulation layer 53 is provided between the second insulation layer 52 and the second FP electrode 12. The third insulation layer 53 has a third thickness (a thickness which corresponds to the above-described (d3−d2), hereinafter, is referred to as a third thickness (d3−d2)) along the Z-axis direction which is thicker than the second thickness (d2−d1). In this example, the third insulation layer 53 is provided on the second insulation layer 52, and the second FP electrode 12 is provided on the third insulation layer 53.

In other words, in the insulating element 50, the step unit in a shape of a cross-sectional step is formed by the first to the third insulation layers 51 to 53 which have different thicknesses from each other. Along the step unit, the first FP electrode 11 and the second FP electrode 12 which have different lengths from each other are formed.

In a plane surface (X-Y plane surface) which is perpendicular to the Z-axis direction, the gate electrode 10 is disposed between the source electrode 20 and the first FP electrode 11. The first FP electrode 11 is disposed between the gate electrode 10 and the second FP electrode 12. The second FP electrode 12 is disposed between the first FP electrode 11 and the drain electrode 30.

The gate electrode 10 includes a first end ed1 on the drain electrode 30 side. The drain electrode 30 includes a second end ed2 on the gate electrode 10 side. The first FP electrode 11 includes a third end ed3 on the drain electrode 30 side. The second FP electrode 12 includes a fourth end ed4 on the drain electrode 30 side. The third end ed3 is disposed between the first end ed1 and the fourth end ed4, and the fourth end ed4 is disposed between the third end ed3 and the second end ed2.

For example, in a case where a distance (distance between the gate and the drain) between the first end ed1 of the gate electrode 10 and the second end ed2 of the drain electrode 30 is Lgd, the first FP electrode 11 is disposed so that a distance (for example, a distance which corresponds to L1) between the first end ed1 of the gate electrode 10 and the third end ed3 of the first FP electrode 11 is approximately ¼ of the Lgd. In addition, the second FP electrode 12 is disposed so that a distance (for example, a distance which corresponds to L1+L2) between the first end ed1 of the gate electrode 10 and the fourth end ed4 of the second FP electrode 12 is approximately ½ of the Lgd.

The first insulation layer 51, the second insulation layer 52, and the third insulation layer 53 have the first thickness d1, the second thickness (d2−d1), and the third thickness (d3−d2) which are constant, respectively. The relationship thereof is d1<(d2−d1)<(d3−d2). In addition, the first FP electrode 11 and the second FP electrode 12 have the first length L1 and the second length L2, respectively. The relationship thereof is L1<L2.

In the insulating element 50, the step unit in a cross-sectional shape of one or more steps is formed by the ends of the first to the third insulation layers 51 to 53. The thicknesses of the first to the third insulation layers 51 to 53 gradually become thicker as they are farther spaced from the compound semiconductor layer 40. The first electrode 10, the first FP electrode 11, and the second FP electrode 12 are formed along the step unit of the insulating element 50. In this example, a gate-FP structure is made as a single continuous electrode. The length of each of the first FP electrode 11 and the second FP electrode 12 become longer as they are farther spaced from the compound semiconductor layer 40, i.e., electrode 12, spaced farther from the compound semiconductor layer 40, is longer than electrode 11, located closer to the compound semiconductor layer 40 than electrode 12.

Here, for example, a material of the first insulation layer 51 and a material of the second insulation layer 52 are different from each other. The material of the second insulation layer 52 and a material of the third insulation layer 53 are different from each other. For example, an etching rate of the first insulation layer 51 is different from an etching rate of the second insulation layer 52. The etching rate of the second insulation layer 52 is different from an etching rate of the third insulation layer 53. It is possible to selectively perform etching, and to form a cross section of the insulating element 50 into a step shape, by using the difference (difference in the etching rate) in the material of each insulation layer.

The first insulation layer 51 includes a first compound having silicon. The second insulation layer 52 includes a second compound having silicon. The third insulation layer 53 includes a third compound having silicon. A ratio of the number of nitrogen atoms with respect to the number of silicon atoms in the first compound is higher than a ratio of the number of nitrogen atoms with respect to the number of silicon atoms in the second compound. A ratio of the number of nitrogen atoms with respect to the number of silicon atoms in the third compound is higher than the ratio of the number of nitrogen atoms with respect to the number of silicon atoms in the second compound. In addition, a ratio of the number of oxygen atoms with respect to the number of silicon atoms in the second compound is higher than a ratio of the number of oxygen atoms with respect to the number of silicon atoms in the first compound, and is higher than a ratio of the number of oxygen atoms with respect to the number of silicon atoms in the third compound.

For example, the first insulation layer 51 includes silicon nitride. The second insulation layer 52 includes silicon oxide. The third insulation layer 53 includes silicon nitride.

In addition, the ratio of the number of oxygen atoms with respect to the number of silicon atoms in the first compound is higher than the ratio of the number of oxygen atoms with respect to the number of silicon atoms in the second compound. The ratio of the number of oxygen atoms with respect to the number of silicon atoms in the third compound is higher than the ratio of the number of oxygen atoms with respect to the number of silicon atoms in the second compound. In addition, the ratio of the number of nitrogen atoms with respect to the number of silicon atoms in the second compound is higher than the ratio of the number of nitrogen atoms with respect to the number of silicon atoms in the first compound, and is higher than the ratio of the number of nitrogen atoms with respect to the number of silicon atoms in the third compound.

For example, the first insulation layer 51 includes silicon oxide. The second insulation layer 52 includes silicon nitride. The third insulation layer 53 includes silicon oxide.

In other words, the etching rates may be different between the insulation layers which are close to each other in the stacking direction (up-and-down direction). Accordingly, it is possible to selectively perform etching with respect to the insulating element, and to forma cross section of the insulating element in a desired step shape. As a method of etching, for example, any method of dry etching and wet etching may be used. As a method of etching, for example, it is possible to use a reactive ion etching (RIE) method, or the like.

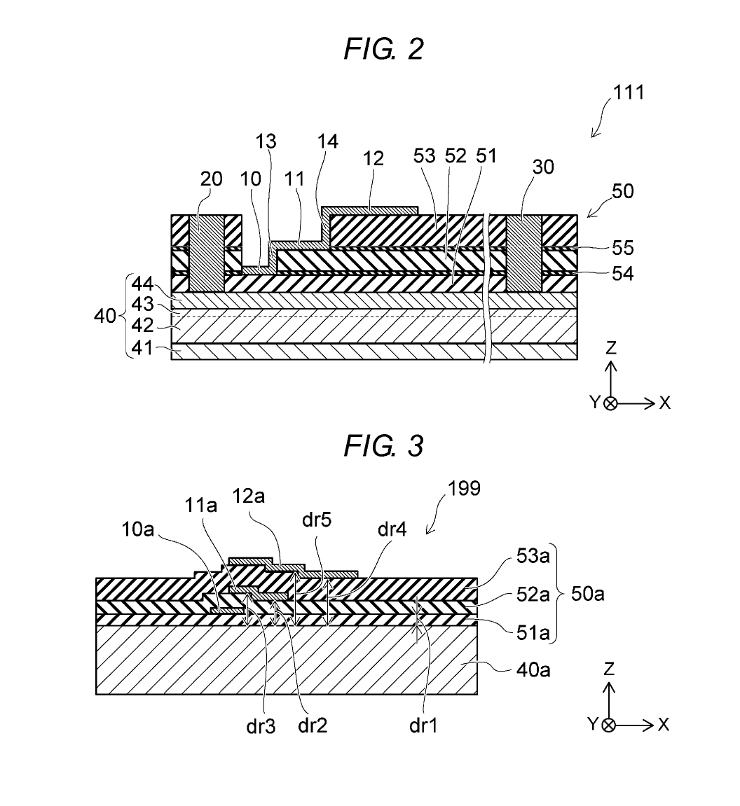

FIG. 2 is a schematic cross-sectional view illustrating an example of another semiconductor device according to the first embodiment.

A semiconductor device 111 of the present example includes the gate electrode 10, the first FP electrode 11, the second FP electrode 12, the source electrode 20, the drain electrode 30, the compound semiconductor layer 40, and the insulating element 50. The insulating element 50 further includes a fourth insulation layer 54 and a fifth insulation layer 55. The fourth insulation layer 54 and the fifth insulation layer 55 function as etching stop layers.

In the present example, as the etching stop layers, the fourth insulation layer 54 and the fifth insulation layer 55 are interposed between the insulation layers of the insulating element 50. Accordingly, it is possible to use materials which have the same etching rate in the first insulation layer 51, the second insulation layer 52, and the third insulation layer 53. In other words, the fourth insulation layer 54 is provided between the first insulation layer 51 and the second insulation layer 52. The fourth insulation layer 54 may extend between the gate electrode 10 and the first insulation layer 51. The fifth insulation layer 55 is provided between the second insulation layer 52 and the third insulation layer 53. The fifth insulation layer 55 may extend between the first FP electrode 11 and the second insulation layer 52.

The first insulation layer 51 includes a first compound having silicon. The second insulation layer 52 includes a second compound having silicon. The third insulation layer 53 includes a third compound having silicon. The fourth insulation layer 54 includes a fourth compound having silicon. The fifth insulation layer 55 includes a fifth compound having silicon. Each of a ratio of the number of oxygen atoms with respect to the number of silicon atoms in the first compound, a ratio of the number of oxygen atoms with respect to the number of silicon atoms in the second compound, and a ratio of the number of oxygen atoms with respect to the number of silicon atoms in the third compound, is different from each of a ratio of the number of oxygen atoms with respect to the number of silicon atoms in the fourth compound and a ratio of the number of oxygen atoms with respect to the number of silicon atoms in the fifth compound. In addition, each of a ratio of the number of nitrogen atoms with respect to the number of silicon atoms in the first compound, a ratio of the number of nitrogen atoms with respect to the number of silicon atoms in the second compound, and a ratio of the number of nitrogen atoms with respect to the number of silicon atoms in the third compound, is different from each of a ratio of the number of nitrogen atoms with respect to the number of silicon atoms in the fourth compound and a ratio of the number of nitrogen atoms with respect to the number of silicon atoms in the fifth compound.

For example, it is possible to include silicon nitride as the first to the third insulation layers 51 to 53, and to include silicon oxide as the fourth and the fifth insulation layers 54 and 55. In contrast, silicon oxide may be included as the first to the third insulation layers 51 to 53, and silicon nitride may be included as the fourth and the fifth insulation layers 54 and 55.

In this manner, according to the embodiment, for example, the step unit in a step shape is provided by the plurality of insulation layers which have different thicknesses from each other, and the gate FP electrode is provided along the step unit. Extending away from the compound semiconductor layer and from the source electrode 20 locations, the thickness of the insulation layer 50 gradually becomes thicker (as a result of the presence of additional sub-layers), and the length of the FP electrode becomes longer. Accordingly, it is possible to reduce the electric field which is generated at the lower part of the electrode. Accordingly, it is possible to provide a semiconductor device having a high breakdown voltage.

In addition, in the embodiment, a case where three insulation layers and two FP electrodes are provided has been illustrated as an example. In the present embodiment and in another embodiment which will be described later, it is possible to similarly employ a case where four or more insulation layers and three or more FP electrodes are provided.

FIG. 3 is a schematic cross-sectional view illustrating an example of a semiconductor device according to a reference example.

A semiconductor device 199 includes a gate electrode 10a, a first FP electrode 11a, a second FP electrode 12a, a compound semiconductor layer 40a, and an insulating element 50a. The insulating element 50a includes a first insulation layer 51a, a second insulation layer 52a, and a third insulation layer 53a.

The first insulation layer 51a is provided on the compound semiconductor layer 40a. The gate electrode 10a is provided on the first insulation layer 51a. The second insulation layer 52a is provided on the gate electrode 10a and the first insulation layer 51a. The first FP electrode 11a is provided on the second insulation layer 52a. The third insulation layer 53a is provided on the first FP electrode 11a and the second insulation layer 52a. The second FP electrode 12a is provided on the third insulation layer 53a. In other words, the semiconductor device 199 is formed by alternately stacking the insulation layers and the electrodes.

Here, a potential difference between the FP electrode and the compound semiconductor layer is substantially constant. When the insulation layer is sandwiched between the FP electrode and the compound semiconductor layer, there is a case where the distance between the FP electrode and the compound semiconductor layer is not constant and the electric field at the lower part of the FP electrode locally changes. In the reference example of FIG. 3, since the first insulation layer 51a has a constant thickness, a distance dr1 between the compound semiconductor layer 40a and the gate electrode 10a is constant. However, the second insulation layer 52a is offset upwardly as much as a thickness of the gate electrode 10a. On the second insulation layer 52a, portions thereof have different thicknesses from each other. For this reason, a distance between the compound semiconductor layer 40a and the first FP electrode 11a is not constant (distance dr2<distance dr3). The third insulation layer 53a is offset upwardly as much as a thickness of the first FP electrode 11a. In the third insulation layer 53a, portions thereof have different thicknesses from each other. For this reason, a distance between the compound semiconductor layer 40a and the second FP electrode 12a is not constant (distance dr4<distance dr5).

In other words, thicknesses along the X-axis direction of both the second insulation layer 52a and the third insulation layer 53a are not constant. The electric field at the lower part of the FP electrode changes according to the thickness of the insulation layer. For this reason, when the thickness of the insulation layer locally changes, the electric field at the lower part of the FP electrode locally changes, and thus, it is not possible to achieve a desired effect of electric field relaxation. As a result, there is a possibility of deterioration of breakdown voltage characteristics.

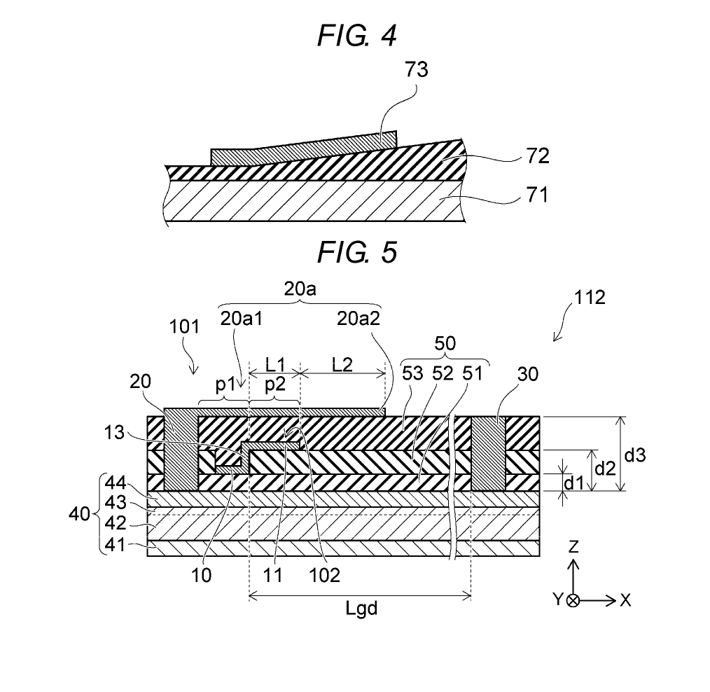

FIG. 4 is a schematic view illustrating an example of an ideal FP structure.

As illustrated in FIG. 4, an insulating element (insulation layer) 72 is provided on a compound semiconductor layer 71, and an FP electrode 73 is provided on the insulating element 72. Electric field characteristics of the FP electrode are determined by a thickness of the insulation layer and a length of the FP electrode. In addition, in order to enhance the effect of electric field relaxation, it is desirable that the length of the FP electrode be set to be relatively long to a certain extent. In order to set the length of the FP electrode to be long, greater thickness of the insulation layer is necessary. Therefore, in order to achieve the desired effect of the electric field reduction, it is desirable that the thicknesses of the individual insulation sub-layers gradually become thicker and thus their upper surfaces extend farther from the compound semiconductor layer, and the length of the segments of the FP electrode on each sub-layer gradually become longer. Accordingly, it is possible to suppress a significant local change of the electric field, and to enhance the effect of the electric field reduction.

According to the description above, a gently inclined structure illustrated in FIG. 4 is considered as the most ideal structure. However, it is extremely difficult to make a structure in which the insulation layer is inclined and this structure is not realistic.

In contrast, according to the embodiment illustrated in FIGS. 1A and 1B, and FIG. 2, in the insulating element 50, the step unit is formed by the differing the distance of the ends of the first to the third insulation layers 51 and 53 from the source electrode 20, and enlarging the height of each step by enlarging the thickness of each of the insulating layers as the later insulating layers are stacked on earlier applied insulating layers. The thicknesses of the first to the third insulation layers 51 and 53 gradually become thicker as they are spaced from the compound semiconductor layer 40. The gate electrode 10, the first FP electrode 11, and the second FP electrode 12 are sequentially formed along the step unit of the insulating element 50. The length of each of the first FP electrode 11 and the second FP electrode 12 becomes longer as they are farther spaced from the compound semiconductor layer 40.

In other words, according to the embodiment, it is possible to provide an ideal FP structure which is close to the inclined structure illustrated in FIG. 4. Accordingly, it is possible to enhance the effect of the electric field relaxation. As a result, it is possible to provide a semiconductor device having a high breakdown voltage. In addition, as compared to making the inclined structure, it is possible that the FP structure of the embodiment is simply made. It is possible to make the FP structure and deposit all of the electrodes (source, drain, gate and FP) in one formation process. Furthermore, it is possible to reduce roughness in the surface flatness of an element structure.

### Second Embodiment

FIG. 5 is a schematic cross-sectional view illustrating an example of a semiconductor device according to a second embodiment.

A semiconductor device 112 of the embodiment includes the compound semiconductor layer 40, the first conductive element 101, a second conductive element 102, and the insulating element 50.

The compound semiconductor layer 40 includes the first semiconductor layer 41, the second semiconductor layer 42, and the third semiconductor layer 44, for example.

The insulating element 50 includes the first insulation layer 51, the second insulation layer 52, and the third insulation layer 53. The first insulation layer 51 is provided on the third semiconductor layer 44. The second insulation layer 52 is provided on the first insulation layer 51. The third insulation layer 53 is provided on the second insulation layer 52.

The first conductive element 101 includes the source electrode 20 (first conductive region) and a second FP electrode 20a. The source electrode 20 is electrically connected to the compound semiconductor layer 40. For example, the source electrode 20 is in contact with the compound semiconductor layer 40. The second FP electrode 20a includes a first FP part 20a1 (second conductive region) and a second FP part 20a2 (third conductive region). The first FP part 20a1 includes a first part p1 and a second part p2. The first part p1 is spaced from the compound semiconductor layer 40 in the Z-axis direction. The first part p1 is electrically connected to the source electrode 20, and is provided on the third insulation layer 53. The second part p2 is aligned with the first part p1 in the X-axis direction. The second FP part 20a2 is electrically connected to the second part p2, and is provided on the third insulation layer 53. The second FP part 20a2 is aligned with the second part p2 in the X-axis direction.

The second conductive element 102 includes the gate electrode 10 (fourth conductive region) and the first FP electrode 11 (fifth conductive region). The gate electrode 10 is provided on the first insulation layer 51 between the compound semiconductor layer 40 and the first part p1. The first FP electrode 11 is provided on the second insulation layer 52 between the compound semiconductor layer 40 and the second part p2. The first FP electrode 11 is electrically connected to the gate electrode 10.

The insulating element 50 is provided between the compound semiconductor layer 40 and the second conductive element 102, between the second conductive element 102 and the first FP part 20a1, and between the compound semiconductor layer 40 and the second FP part 20a2. In other words, the insulating element 50 is provided between the compound semiconductor layer 40 and the gate electrode 10, between the gate electrode 10 and the first part p1, between the compound semiconductor layer 40 and the first FP electrode 11, between the first FP electrode 11 and the second part p2, and between the compound semiconductor layer 40 and the second FP part 20a2.

The first distance along the Z-axis direction between the compound semiconductor layer 40 and the gate electrode 10 is shorter than the second distance along the Z-axis direction between the compound semiconductor layer 40 and the first FP electrode 11. The third distance between the compound semiconductor layer 40 and the second FP part 20a2 is longer than the second distance. The difference between the first distance and the second distance is smaller than the difference between the second distance and the third distance. The first length along the X-axis direction of the first FP electrode 11 is shorter than the second length along the X-axis direction of the second FP part 20a2.

In other words, the first distance dl along the Z-axis direction between the compound semiconductor layer 40 and the gate electrode 10, the second distance d2 along the Z-axis direction between the compound semiconductor layer 40 and the first FP electrode 11, and the third distance d3 along the Z-axis direction between the compound semiconductor layer 40 and the second FP part 20a2 satisfy a relationship of d1<(d2−d1)<(d3−d2).

The first length L1 along the X-axis direction of the first FP electrode 11 and the second length L2 along the X-axis direction of the second FP part 20a2 satisfy a relationship of L1<L2.

The semiconductor device 112 further includes the drain electrode 30 (third conductive element). The drain electrode 30 is spaced from the first conductive element 101 in the X-axis direction. The drain electrode 30 is electrically connected to the compound semiconductor layer 40. For example, the drain electrode 30 is in contact with the compound semiconductor layer 40. The second conductive element 102 is disposed between the source electrode 20 and the drain electrode 30.

In the embodiment, the first FP electrode 11 is electrically connected to the gate electrode 10. The second FP electrode 20a is electrically connected to the source electrode 20.

The first FP electrode 11 is spaced from the compound semiconductor layer 40 in the Z-axis direction, and is electrically connected to the gate electrode 10. The first FP electrode 11 has the first length L1 in the X-axis direction. In the example, the gate electrode 10 and the first FP electrode 11 are linked to each other by the first linking unit 13.

The second FP electrode 20a is electrically connected to the source electrode 20. The second FP electrode 20a includes the first FP part 20a1 and the second FP part 20a2. The second FP part 20a2 extends further than the first FP electrode 11 in the X-axis direction, and is spaced from the compound semiconductor layer 40 in the Z-axis direction. The second length L2 of the second FP part 20a2 is longer than the first length L1 of the first FP electrode 11.

The first insulation layer 51 is provided between the compound semiconductor layer 40 and the gate electrode 10, between the compound semiconductor layer 40 and the first FP electrode 11, and between the compound semiconductor layer 40 and the second FP part 20a2. The first insulation layer 51 has the first thickness d1 in the Z-axis direction. In this example, the first insulation layer 51 is provided on the compound semiconductor layer 40, and the gate electrode 10 is provided on the first insulation layer 51.

The second insulation layer 52 is provided between the first insulation layer 51 and the first FP electrode 11, and between the first insulation layer 51 and the second FP part 20a2. The second insulation layer 52 has the second thickness (d2−d1) which is thicker than the first thickness d1 in the Z-axis direction. In this example, the second insulation layer 52 is provided on the first insulation layer 51, and the first FP electrode 11 is provided on the second insulation layer 52.

The third insulation layer 53 is provided between the second conductive element 102 and the first FP part 20a1, and between the second insulation layer 52 and the second FP part 20a2. The third insulation layer 53 has the third thickness (d3−d2) which is thicker than the second thickness (d2−d1) in the Z-axis direction. In this example, the third insulation layer 53 is provided on the second insulation layer 52, and the second FP electrode 20a is provided on the third insulation layer 53.

In the description above, the first insulation layer 51, the second insulation layer 52, and the third insulation layer 53 have the first thickness d1, the second thickness (d2−d1), and the third thickness (d3−d2) which are constant, respectively. The relationship thereof is d1<(d2−d1)<(d3−d2). In addition, the first FP electrode 11 has the first length L1. The second FP part 20a2 of the second FP electrode 20a has the second length L2. The relationship thereof is L1<L2.

In other words, in the insulating element 50, the step unit in a shape of a cross-sectional step is formed by the first and the second insulation layers 51 and 52. The thicknesses of the first to the third insulation layers 51 to 53 are thicker the farther they are from the compound semiconductor layer 40. The gate electrode 10 and the first FP electrode 11 are formed along the step unit of the insulating element 50. The second FP electrode 20a is provided on an upper side of the gate electrode 10 and the first FP electrode 11, and is formed to be more protruded than the first FP electrode 11 in the X-axis direction.

In this manner, according to the embodiment, for example, the step unit in a step shape is provided on the plurality of insulation layers which have different thicknesses from each other, the gate FP electrode is provided along the step unit, and further, the source FP electrode is provided on the upper side of the gate FP electrode. As being separated from the compound semiconductor layer, the thickness of the insulation layer gradually becomes thicker, and the length of the FP electrode gradually becomes longer. Accordingly, it is possible to reduce the electric field which is generated at the lower part of the electrode. Accordingly, it is possible to provide a semiconductor device having a high breakdown voltage.

### Third Embodiment

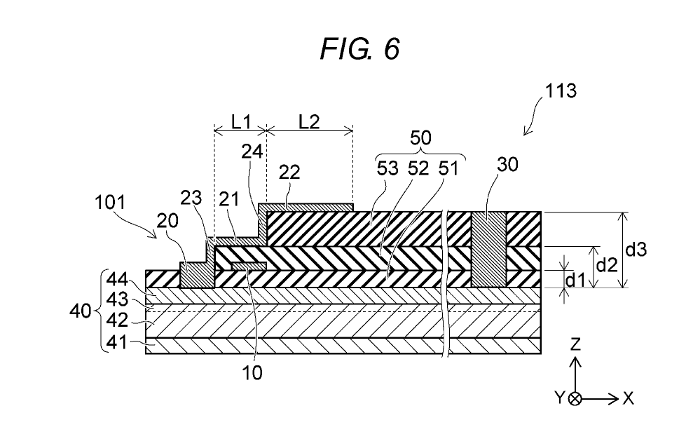

FIG. 6 is a schematic cross-sectional view illustrating an example of a semiconductor device according to a third embodiment.

A semiconductor device 113 of the embodiment includes the compound semiconductor layer 40, the first conductive element 101, the gate electrode 10 (second conductive element), and the insulating element 50.

The compound semiconductor layer 40 includes the first semiconductor layer 41, the second semiconductor layer 42, and the third semiconductor layer 44, for example.

The insulating element 50 includes the first insulation layer 51, the second insulation layer 52, and the third insulation layer 53. The first insulation layer 51 is provided on the third semiconductor layer 44. The second insulation layer 52 is provided on the first insulation layer 51. The third insulation layer 53 is provided on the second insulation layer 52.

The first conductive element 101 includes the source electrode 20 (first conductive region), a first FP electrode 21 (second conductive region), and a second FP electrode 22 (third conductive region). The source electrode 20 is electrically connected to the compound semiconductor layer 40. For example, the source electrode 20 is in contact with the compound semiconductor layer 40. The first FP electrode 21 is electrically connected to the source electrode 20, and is provided on the second insulation layer 52. The second FP electrode 22 is electrically connected to the first FP electrode 21, and is provided on the third insulation layer 53. Each of the first FP electrode 21 and the second FP electrode 22 are spaced from the compound semiconductor layer 40 in the Z-axis direction.

In the embodiment, the gate electrode 10 is provided on the first insulation layer 51 between the compound semiconductor layer 40 and the first FP electrode 21.

The insulating element 50 is provided between the compound semiconductor layer 40 and the gate electrode 10, between the gate electrode 10 and the first FP electrode 21, and between the compound semiconductor layer 40 and the second FP electrode 22.

The first distance along the Z-axis direction between the compound semiconductor layer 40 and the gate electrode 10 is shorter than the second distance along the Z-axis direction between the compound semiconductor layer 40 and the first FP electrode 21. The third distance between the compound semiconductor layer 40 and the second FP electrode 22 is longer than the second distance. The difference between the first distance and the second distance is smaller than the difference between the second distance and the third distance. The first length along the X-axis direction of the first FP electrode 21 is shorter than the second length along the X-axis direction of the second FP electrode 22.

In other words, the first distance dl along the Z-axis direction between the compound semiconductor layer 40 and the gate electrode 10, the second distance d2 along the Z-axis direction between the compound semiconductor layer 40 and the first FP electrode 21, and the third distance d3 along the Z-axis direction between the compound semiconductor layer 40 and the second FP electrode 22 satisfy a relationship of d1<(d2−d1)<(d3−d2).

The first length L1 along the X-axis direction of the first FP electrode 21 and the second length L2 along the X-axis direction of the second FP electrode 22 satisfy a relationship of L1<L2.

The semiconductor device 113 further includes the drain electrode 30 (third conductive element). The drain electrode 30 is electrically connected to the compound semiconductor layer 40. For example, the drain electrode 30 is in contact with the compound semiconductor layer 40. The gate electrode 10 is disposed between the source electrode 20 and the drain electrode 30.

In the embodiment, the first FP electrode 21 and the second FP electrode 22 are electrically connected to the source electrode 20.

The first FP electrode 21 is spaced from the compound semiconductor layer 40 in the Z-axis direction, and is electrically connected to the source electrode 20. The first FP electrode 21 has the first length L1 in the X-axis direction. In this example, the source electrode 20 and the first FP electrode 21 are linked to each other by a first linking unit 23.

The second FP electrode 22 is spaced from the compound semiconductor layer 40 in the Z-axis direction, and is electrically connected to the first FP electrode 21. The second FP electrode 22 has the second length L2 which is longer than the first length L1 in the X-axis direction. In this example, the first FP electrode 21 and the second FP electrode 22 are linked to each other by a second linking unit 24.

The first insulation layer 51 is provided between the compound semiconductor layer 40 and the gate electrode 10, and between the compound semiconductor layer 40 and the second FP electrode 22. The first insulation layer 51 has the first thickness d1 in the Z-axis direction. In this example, the first insulation layer 51 is provided on the compound semiconductor layer 40, and the gate electrode 10 is provided on the first insulation layer 51.

The second insulation layer 52 is provided between the gate electrode 10 and the first FP electrode 21, and between the first insulation layer 51 and the second FP electrode 22. The second insulation layer 52 has the second thickness (d2−d1) which is thicker than the first thickness d1 in the Z-axis direction. In this example, the second insulation layer 52 is provided on the first insulation layer 51, and the first FP electrode 21 is provided on the second insulation layer 52.

The third insulation layer 53 is provided between the second insulation layer 52 and the second FP electrode 22. The third insulation layer 53 has the third thickness (d3−d2) which is thicker than the second thickness (d2−d1) in the Z-axis direction. In this example, the third insulation layer 53 is provided on the second insulation layer 52, and the second FP electrode 22 is provided on the third insulation layer 53.

In the description above, the first insulation layer 51, the second insulation layer 52, and the third insulation layer 53 have the first thickness d1, the second thickness (d2−d1), and the third thickness (d3−d2) which are constant, respectively. The relationship thereof is d1<(d2−d1)<(d3−d2). In addition, the first FP electrode 21 has the first length L1. The second FP electrode 22 has the second length L2. The relationship thereof is L1<L2.

In other words, in the insulating element 50, the step unit in a shape of a cross-sectional step is formed by the first to the third insulation layers 51 and 53. The thicknesses of the first to the third insulation layers 51 to 53 become thicker the farther they are from the compound semiconductor layer 40. The source electrode 20, the first FP electrode 21, and the second FP electrode 22 are formed along the step unit of the insulating element 50. The first FP electrode 21 is formed to be spaced from the gate electrode 10. In this example, a source FP structure is made by one time of electrode formation. The relative lengths of the first FP electrode 21 and the second FP electrode 22 become longer the farther they are spaced from the compound semiconductor layer 40.

In this manner, according to the embodiment, for example, the step unit in a step shape is provided on the plurality of insulation layers which have different thicknesses from one another, and the source FP electrode is provided along the step unit. The length of the FP electrode becomes longer, the farther it is spaced from the compound semiconductor layer 40, and the insulation layer is gradually increased in thickness, in a step wise manner, to supply that spacing of the FP electrode (21, 22) form the compound semiconductor layer. Accordingly, it is possible to reduce the electric field which is generated at the lower part of the electrode. Accordingly, it is possible to provide a semiconductor device having a high breakdown voltage.

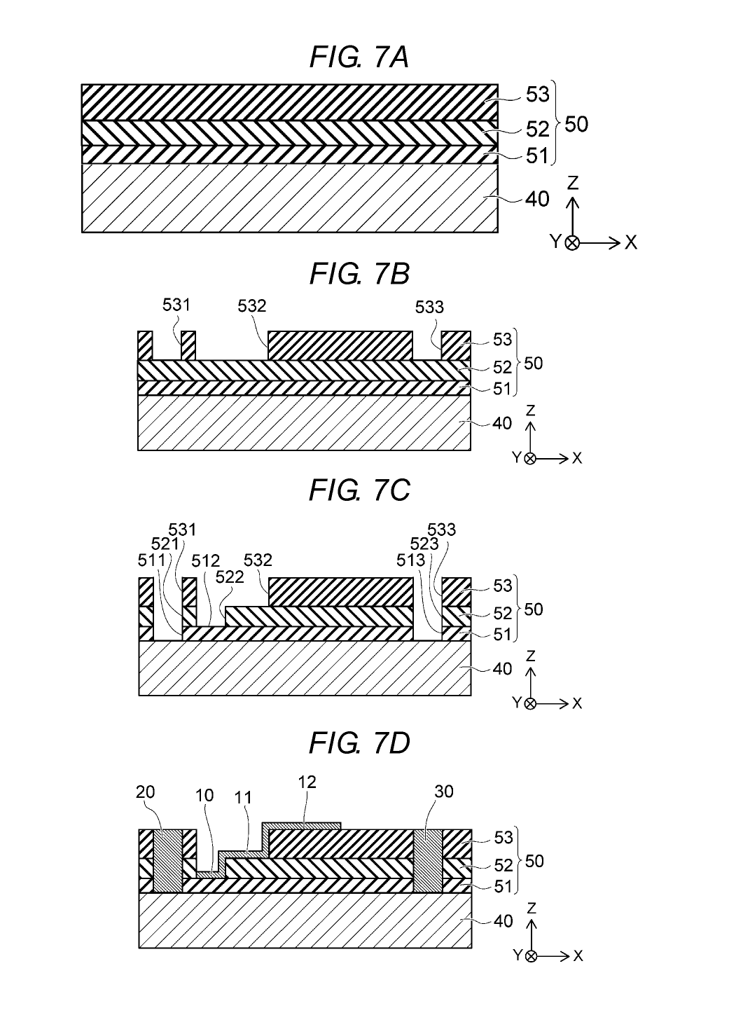

FIGS. 7A to 7D are schematic cross-sectional views illustrating an example of a manufacturing process of the semiconductor device according to the embodiment.

As illustrated in FIG. 7A, the first insulation layer 51, the second insulation layer 52, and the third insulation layer 53 are formed on the compound semiconductor layer 40 in that order. As the first insulation layer 51, for example, silicon oxide is used. The first insulation layer 51 is formed by using an atomic layer deposition (ALD) method, for example. As the second insulation layer 52, for example, silicon nitride, which has different etching rate from that of silicon oxide, is used. The second insulation layer 52 is formed by using a plasma chemical vapor deposition (CVD) method, for example. As the third insulation layer 53, for example, silicon oxide, which has different etching rate from that of silicon nitride, is used. The third insulation layer 53 is formed by using a TEOS-CVD method, for example.

The first to the third insulation layers 51 to 53 may be heat-treated, and film quality thereof may be improved. For example, after forming the insulating element 50 including the first to the third insulation layers 51 to 53, a wafer is input into a heat treatment furnace and heated for a predetermined period of time. The heat treatment temperature is 800° C., for example. Accordingly, it is possible to combine uncombined element of the layers in the insulating element 50. For example, where a hydrogen based deposition chemistry, such as silane or TEOS, are used as the silicon precursor for the silicon oxide and silicon nitride films, heat treatment causes unreacted or not fully reacted (incorporated) adjacent silicon molecules to react, and the structure of the insulating element 50 becomes more dense, and for example, it is possible to improve the insulation breakdown voltage of the insulation region.

As illustrated in FIG. 7B, on the third insulation layer 53, a source first opening 531, a gate first opening 532, and a drain first opening 533, are formed. The source first opening 531 is formed at a position where the source electrode 20 is to be provided. The gate first opening 532 is formed at a position where the gate electrode 10 and the first FP electrode 11 are to be provided. The drain first opening 533 is formed at a position where the drain electrode 30 is to be provided. The source first opening 531, the gate first opening 532, and the drain first opening 533 are formed using a patterned mask (not shown) over the third insulation layer 53, and selective etching conditions, i.e., an etching precursor(s) which is highly selective to etch the material of third insulation layer 53 and not etch the second insulation layer 52, using the RIE method, for example. In other words, it is preferable to use conditions for etching the third insulation layer 53 without etching the second insulation layer 52. Accordingly, it is possible to easily form the source first opening 531, the gate first opening 532, and the drain first opening 533.

As illustrated in FIG. 7C, using an additional patterned mask (not shown), etching is selectively performed similarly to the description above, and a source second opening 521, a gate second opening 522, and a drain second opening 523 are formed on the second insulation layer 52. When the gate second opening 522 is formed, a surface 512 of the first insulation layer 51 is exposed. The step unit in a shape of a cross-sectional step is formed by the gate first opening 532 and the gate second opening 522. Furthermore, using a third patterned mask (not shown), etching is selectively performed on the first insulation layer 51, and a source third opening 511 and a drain third opening 513 are formed.

As illustrated in FIG. 7D, on the surface 512 of the first insulation layer 51, the gate electrode 10 is formed, and the first FP electrode 11 and the second FP electrode 12 are formed along the step unit formed by the gate first opening 532 and the gate second opening 522. In this example, since the first FP electrode 11 and the second FP electrode 12 are formed to be integrated with the gate electrode 10, it is possible to shorten an FP forming process.

The source electrode 20 is formed inside the source first opening 531, the source second opening 521, and the source third opening 511. Similarly, the drain electrode 30 is formed inside the drain first opening 533, the drain second opening 523, and the drain third opening 513. Accordingly, it is possible to manufacture the semiconductor device 110.

In addition, in the description above, a case where the plurality of insulation layers having different etching rates from each other are employed has been described. The embodiment is not limited thereto. For example, an etching stop layer may be used between adjacent insulating layers. In a case where the etching stop layer is used, it is possible to employ the plurality of insulation layers 50, 51 and 52 having the same etching rate in the same etch chemistry.

In the specification, the nitride semiconductor includes a semiconductor having all of the compositions in which composition ratios of x, y, and z are changed in their ranges in a chemical formula BₓIn_{y}Al_{z}Ga_{1-x-y-z}N (0≦x≦1, 0≦y≦1, 0≦z≦1, x+y+z≦1). Furthermore, in the above-described chemical formula, a semiconductor further containing a V group element other than N (nitrogen), a semiconductor further containing various types of elements which are added for controlling various types of characteristics, such as a conductive type, and a semiconductor further containing various types of elements which are included unintentionally, are also included in the examples of the nitride semiconductor.

According to the embodiment, it is possible to provide a semiconductor device having a high breakdown voltage.

Above, with reference to specific examples, the embodiments have been described. However, the exemplary embodiment is not limited to the specific examples. For example, a specific configuration of each configuration element, such as the compound semiconductor layer, the insulating element, and the first conductive element, is included in the scope of the exemplary embodiment when the exemplary embodiment is similarly performed by appropriate selection within the scope well-known by those skilled in the art, and similar effects is obtained.

In addition, a combination of two or more elements among any of each specific examples within a technically possible range, is also included in the scope of the exemplary embodiment when the spirit of the exemplary embodiment is included.

In addition, based on the above-described semiconductor device as an embodiment of the exemplary embodiment, all of the semiconductor devices which can be appropriately design-changed and performed by those skilled in the art are also included in the scope of the exemplary embodiment when the spirit of the exemplary embodiment is included.

In addition, in the category of the idea of the exemplary embodiment, those who skilled in the art are conceive various modification examples and change examples, and such the modification examples and the change examples are also understood as those included in the scope of the exemplary embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a compound semiconductor layer;
a first conductive element including a plurality of conductive regions, each of the plurality of conductive regions spaced a different distance in a first direction from the compound semiconductor layer; and
an insulating element located between the compound semiconductor layer and the first conductive element, and
wherein a length, along a second direction which intersects the first direction, of each of the plurality of conductive regions is longer in conductive regions which are spaced farther from the compound semiconductor layer than conductive layers spaced from, and closer to the compound semiconductor layer.

2. The device according to claim 1,
wherein the plurality of conductive regions include a first conductive region, a second conductive region which is electrically connected to the first conductive region, and a third conductive region which is electrically connected to the second conductive region,
wherein a first distance along the first direction between the compound semiconductor layer and the first conductive region is smaller than a second distance along the first direction between the compound semiconductor layer and the second conductive region,
wherein a third distance along the first direction between the compound semiconductor layer and the third conductive region is greater than the second distance,
wherein the difference between the first distance and the second distance is less than the difference between the second distance and the third distance, and
wherein a first length along the second direction which intersects the first direction of the second conductive region is less than a second length along the second direction of the third conductive region.

3. The device according to claim 2, further comprising:
a second conductive element which is electrically connected to the compound semiconductor layer, and
a third conductive element which is spaced from the second conductive element in the second direction, and is electrically connected to the compound semiconductor layer,
wherein the first conductive element is disposed between the second conductive element and the third conductive element.

4. The device according to claim 3,
wherein the first conductive region is a gate electrode,
wherein the second conductive element is a source electrode, and
wherein the third conductive element is a drain electrode.

5. The device according to claim 2,
wherein, along the first direction, the distance between the first conductive element and the compound semiconductor layer changes in a step shape between the first distance and the second distance, and again changes in a step shape between the second distance and the third distance.

6. The device according to claim 2,
wherein the insulating element includes:
a first insulation layer which is provided between the compound semiconductor layer and the first conductive region, between the compound semiconductor layer and the second conductive region, and between the compound semiconductor layer and the third conductive region;
a second insulation layer which is provided between the first insulation layer and the second conductive region and between the first insulation layer and the third conductive region; and
a third insulation layer which is provided between the second insulation layer and the third conductive region.

7. The device according to claim 6,
wherein a material of the first insulation layer is different from a material of the second insulation layer, and
wherein the material of the second insulation layer is different from a material of the third insulation layer.

8. The device according to claim 7, wherein the first insulation layer and the third insulation layer comprise the same material.

9. The semiconductor device of claim 8, wherein the first insulation layer and third insulation layer comprise one of silicon oxide and silicon nitride, and the second insulation layer comprises the other of silicon oxide and silicon nitride.

10. The device of claim 7, further including a fourth insulation layer interposed between the first insulation layer and the second insulation layer, and a fifth insulation layer interposed between the second insulation layer and the third insulation layer, wherein
the first, second and third insulation layers are the same material, and the fourth and fifth insulation layers are a second, different material.

11. A semiconductor device, comprising:
a compound semiconductor region;
a multi-layer insulation region overlying the compound semiconductor region, the multi-layer insulation region comprising a first sub-layer directly overlying the compound semiconductor region, a second sub-layer, having a thickness which is greater than the thickness of the first sub-layer, overlying the first sub-layer, and a third sub-layer, having a thickness which is greater than the thickness of the second sub-layer, overlying the second sub-layer;
a first conductor extending from contact with the compound semiconductor region and through the multi-layer insulation region in a first direction;
a second conductor extending from contact with the compound semiconductor region and through the multi-layer insulation region in the first direction; and
a third conductor extending, in a second direction intersecting the first direction, over the compound semiconductor region at different distances from the compound semiconductor layer over the length of the third conductor, the third conductor isolated from the compound semiconductor region by the insulation region.

12. The semiconductor device of claim 11, wherein the third conductor includes at least a first conductive portion extending, in the second direction, over the first sub-layer, and a second conductive portion extending over the second sub-layer.

13. The semiconductor device of claim 12, wherein the first conductive portion is covered by the second sub-layer.

14. The semiconductor device of claim 12, wherein the third conductor further comprises a third conductive portion extending over the third sub-layer.

15. The semiconductor device of claim 12, wherein the first conductor further comprises an extending portion extending therefrom, in the second direction, over the third sub-layer.

16. The semiconductor device of claim 12, wherein the first conductive portion comprises a gate electrode, and the second conductive portion comprises a field plate electrode.

17. A compound semiconductor device having a compound semiconductor region, comprising:
an insulation region disposed over the compound semiconductor region and extending thereover in a first direction generally coplanar with the compound semiconductor region; and
at least one conductor having a first portion spaced a first distance from the compound semiconductor region and electrically isolated from the compound semiconductor region and extending a first span distance in the first direction, and a second portion spaced a second distance from the compound semiconductor region and electrically isolated from the compound semiconductor region and extending a second span distance in the first direction.

18. The semiconductor device of claim 17, wherein the insulation layer comprises at least a first sub-layer and a second sub-layer, and the first portion of the conductor is disposed on the first sub-layer and the second portion of the conductor is disposed on the second sub-layer.

19. The semiconductor device of claim 17, further comprising:
a second conductor having a first portion spaced a first distance from the compound semiconductor region and electrically isolated from the compound semiconductor region and extending a first span distance in the first direction, and a second portion spaced a second distance from the compound semiconductor region and electrically isolated from the compound semiconductor region and extending a second span distance in the first direction, wherein
the insulation layer comprises at least a first sub-layer and a second sub-layer, and
the one conductor is disposed between the first sub-layer and the second sub-layer, and the second conductor is disposed on the second sub-layer.

20. The semiconductor device of claim 17, wherein the first portion of the at least one conductor comprises a gate electrode.
